(19) United States
(12) Patent Application Publication
(10) Pub. No.: US 2008/0258285 A1
(43) Pub. Date: Oct. 23, 2008

(54) Simplified Substrates for Semiconductor Devices in Package-on-Package Products

(75) Inventors: Peter R. Harper, Lucas, TX (US); James L. Turner, Murphy, TX (US); Kevin P. Lyne, Fairview, TX (US); Kurt Wachtler, Richardson, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/839,613

(22) Filed: Aug. 16, 2007

Related U.S. Application Data
(60) Provisional application No. 60/913,338, filed on Apr. 23, 2007.

(51) Int. Cl. H01L 23/02

(52) U.S. Cl. 257/686; 257/E23.18

(57) ABSTRACT

An insulating sheet-like substrate (601), which has on one surface (601a) a first patterned metal layer (605) with a first (603a) and a second (603b) array of contact pads. The pads of the first array have a first pitch center-to-center, and each pad has a first perimeter. The pads of the second array have a second pitch center-to-center, and each pad has the first perimeter. The substrate has on its other surface (601b) a second patterned metal layer (606) with a third array (607) of contact pads, which has the first pitch center-to-center, and each pad has a third perimeter. Conductive vias (640) between the first and the second metal layers connect contact pads and have a fourth perimeter; the vias are placed in interstitial locations so that the fourth perimeter does not intersect with the first and third perimeters. Vias in interstitial locations can be provided by disposing the first array and the third array so that the first and third perimeters of respective contact pads are concentrically aligned.

This application claims priority under 35 U.S.C. § 119 based on Provisional Application Ser. No. 60/913,338, filed on Apr. 23, 2007.

### FIELD OF THE INVENTION

The present invention is related in general to the field of semiconductor devices and processes, and more specifically to structure, layout, and processes of low profile packages for vertically integrated semiconductor systems.

### DESCRIPTION OF THE RELATED ART

The long-term trend in semiconductor technology to double the functional complexity of its products every 18 months (Moore's rule) has several implicit consequences. First, the higher product complexity should largely be achieved by shrinking the feature sizes of the chip components while holding the package dimensions constant; preferably, even the packages should shrink. Second, the increased functional complexity should be paralleled by an equivalent increase in reliability of the product. Third, the cost per functional unit should drop with each generation of complexity so that the cost of the product with its doubled functionality would increase only slightly.

As for the challenges in semiconductor packaging, the major trends are efforts to shrink the package outline so that the package consumes less area and less height when it is mounted onto the circuit board, and to reach these goals with minimum cost (both material and manufacturing cost). Recently, another requirement was added to this list, namely the need to design packages so that stacking of chips and/or packages becomes an option to increase functional density and reduce device thickness. Furthermore, it is hoped that a successful strategy for stacking chips and packages would shorten the time-to-market of innovative products, which utilize available chips of various capabilities (such as processors and memory chips) and would not have to wait for a redesign of chips.

Recent applications especially for hand-held wireless equipments, combined with ambitious requirements for data volume and high processing speed, place new, stringent constraints on the size and volume of semiconductor components used for these applications. Consequently, the market place is renewing a push to shrink semiconductor devices both in two and in three dimensions, and this miniaturization effort includes packaging strategies for semiconductor devices as well as electronic systems.

### SUMMARY OF THE INVENTION

Applicants recognize an existing need for a structure and system for fabricating a semiconductor device based on a low cost, small thickness substrate, wherein the device becomes adaptable to, and versatile in assembling package-on-package products. Specifically, applicants recognize an existing need for dramatically reducing the cost of an insulating substrate by reducing the number of patterned metal layers, while concurrently increasing the pin count for solder ball attachment. Applicants further recognize the need for preserving solder ball coplanarity in spite of more than one solder ball pitch, and for enhancing routability by allowing selective depopulation of solder ball pads.

One embodiment of the present invention is an insulating sheet-like substrate, which has on one surface a first patterned metal layer with a first and a second array of contact pads. The pads of the first array have a first pitch center-to-center, and each pad has a first perimeter. The pads of the second array have a second pitch center-to-center different from the first pitch, and each pad has the first perimeter. The substrate has on its other surface a second patterned metal layer with a third array of contact pads, which has the first pitch center-to-center, and each pad has a third perimeter. Conductive vias between the first and the second metal layers connect contact pads and have a fourth perimeter; the vias are placed in interstitial locations so that the fourth perimeter does not overlap with the first and third perimeters.

According to the invention, vias in interstitial locations can be provided by disposing the first array and the third array so that the first and third perimeters of respective contact pads are concentrically aligned.

One or more semiconductor chips may be connected to the substrate either by wire bonds or by flip-chip. The contact pads on the surface with the first and second arrays may have attached solder bodies, which connect to a motherboard. The contact pads on the surface with the third array may have attached solder bodies, which connect to another device, frequently a memory component.

Another embodiment of the invention is an insulating sheet-like substrate, which has on one surface a first patterned metal layer with a first and a second array of contact pads. The pads of the first and the second array have a first pitch center-to-center and each pad has a first perimeter. The substrate has on its other surface a second patterned metal layer with a third array of contact pads, which has the first pitch center-to-center and selected contact pads depopulated from the array, and each pad has a third perimeter. Conductive vias between the first and the second metal layers connect aligned contact pads and have a fourth perimeter; the vias are placed in interstitial locations so that the fourth perimeter does not overlap with the first and third perimeters. Routing lines to the contact pads of the third array are distributed in the second metal layer so that required space is provided by the selectively depopulated contact pads. This sacrifice enables a high density of routing line even under the constraint of only two metal layers.

According to the invention, vias in interstitial locations can be provided by disposing the first array and the third array so that the first and third perimeters of respective contact pads are concentrically aligned.

The technical advances represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIGS. 1, 2, and 3 represent different views of a semiconductor device representing an embodiment of the invention.

FIG. 1 is a cross section of the device, illustrating the sheet-like substrate including solder bodies on both surfaces.

FIG. 2 represents the simplified bottom view of the device, illustrating the first substrate surface with solder body arrays of two different pitches according to the invention.

FIG. 3 represents the simplified top view of the device, illustrating the second substrate surface.

FIG. 4A is a schematic cross section of the insulating substrate portion designated “A” in FIG. 1, with metallization and interstitial vias according to the invention.

FIG. 4B is a schematic cross section illustrating fabrication uncertainties of conductive vias and the resulting need for interstitial via positioning.

FIG. 5 depicts a magnified X-ray view of the substrate portion designated “B” in FIG. 2, illustrating aligned contact pads on the surfaces, and interstitial vias.

FIG. 6 is a schematic cross section of a semiconductor package-on-package device, assembled on a motherboard, according to the invention, including solder ball arrays of two different pitches on the bottom surface of the substrate of one package.

FIG. 7 is an X-ray view of a substrate portion of another semiconductor device according to the invention, identifying locations of selectively depopulated contact pads to provide space for routing lines.

### DETAILED DESCRIPTION OF THE PREFERRED EMBODIMENTS

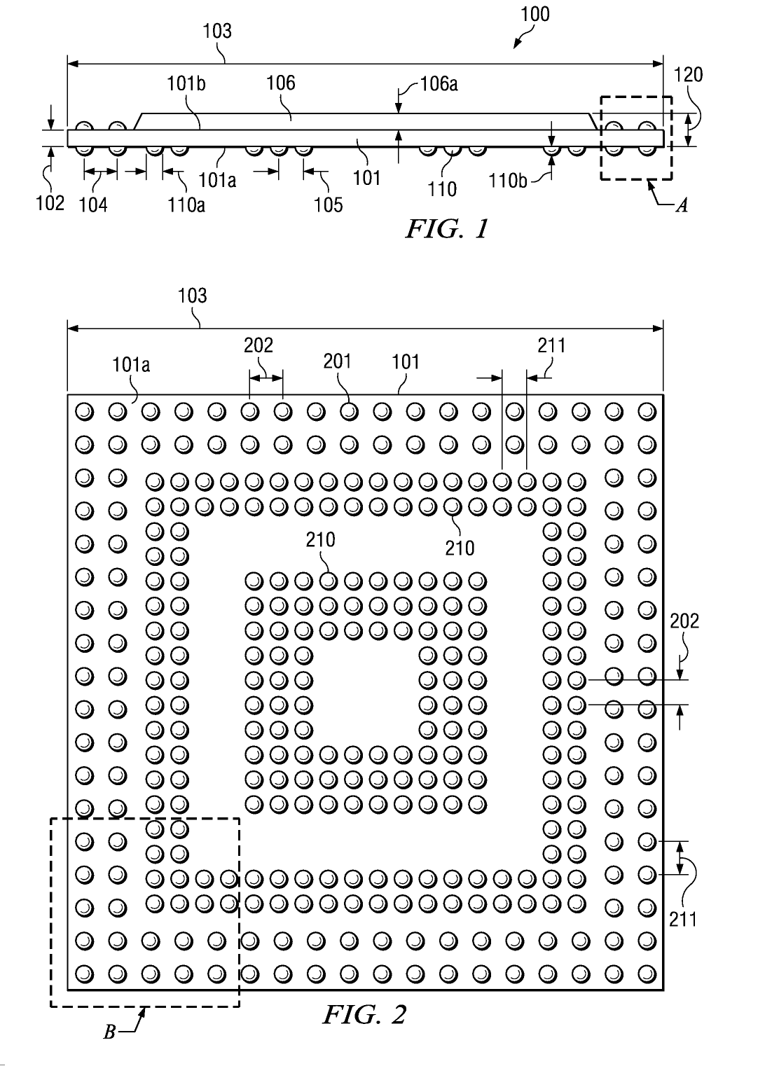

FIGS. 1, 2 and 3 represent different views of a semiconductor device, generally designated 100, as an embodiment of the invention. The example illustrated is a plastic fine-pitch NF BGA (Ball Grid Array). The device includes sheet-like substrate 101, which is made of insulating materials such as a glass-fiber strengthened epoxy, or a ceramic; in the example of FIG. 1, it has a thickness 102 between about 0.26 and 0.34 mm and a side length of about 12 mm. It should be noted that the invention is applicable to many different sizes and thicknesses of substrates.

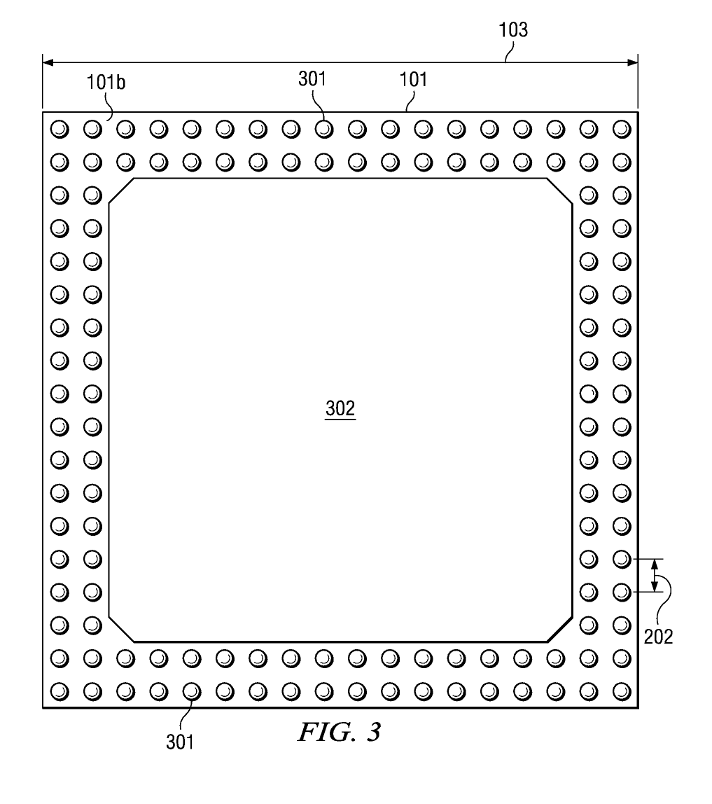

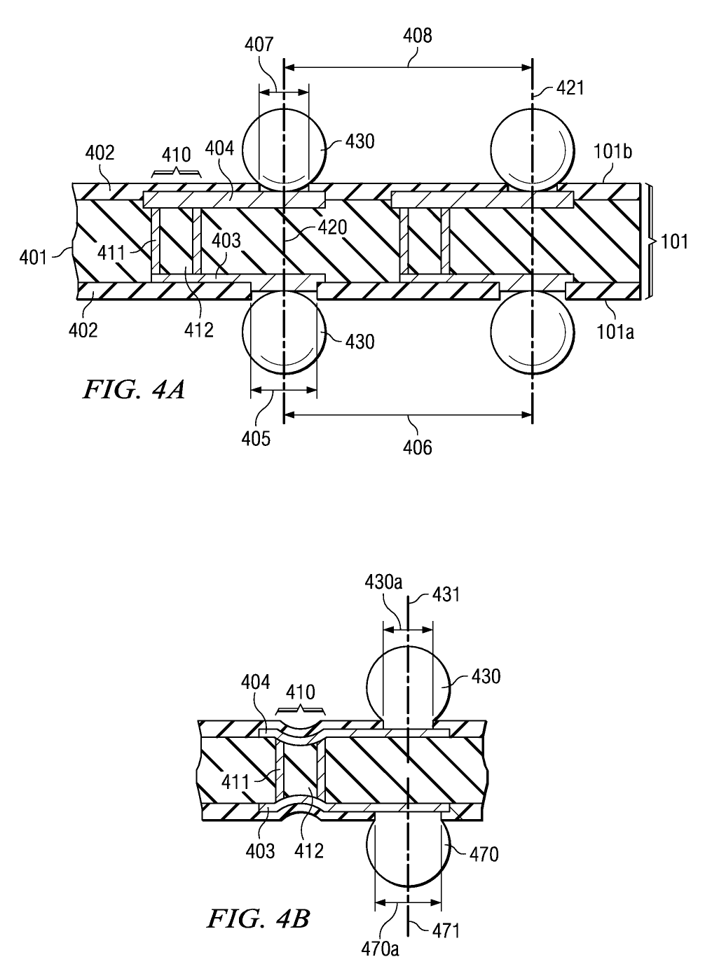

Substrate 101 has a first surface 101a and a second surface 101b. On first surface 101a is a first metal layer and on second surface 101b is a second metal layer (details shown in FIG. 4), preferably copper or a copper alloy. The metal layers are patterned into routing lines (not shown) and contact pads with certain perimeters. The contact pads are arranged in arrays and have pitches 104 and 105, which are discussed in FIGS. 2 and 3. The contact pads are shown in FIG. 1 with solder balls 110 already attached; the solder material preferably includes a tin-based alloy in an approximately hemispherical shape. Solder material is generally referred to as balls, whether or not the actual shape is spherical; in addition, another expression frequently used is reflow body, referring to metals or alloys melting at temperatures between about 200 and approximately 450° C. The diameter 110a of the solder bodies may vary from about 0.2 to 0.4 mm and is preferably between about 0.25 and 0.35 mm, with a height 110b between 0.15 and 0.28 mm. In general, bumps 110 serve mechanical attachment as well as electrical conductivity; consequently, bumps 110 need to be conductive. In some device types, bumps 110 may be made of copper, copper alloy, or gold.

FIG. 1 shows in the center of substrate 101 the encapsulation 106 of a semiconductor chip (not shown in FIG. 1). Encapsulation 106 has a height 106a between about 0.24 and 0.30 mm, dependent on the assembly of the chip by flip-chip or by wire bonding. Consequently, the overall height 120 of the device 100 may vary, but should preferably not surpass 0.9 mm and thus keep the total device thickness under one millimeter.

Device portion “A” is discussed in the magnified cross section of FIG. 4A.

The bottom view of device 100 in FIG. 2 shows the first surface 101a of substrate 101 with the first and the second array of contact pads provided by the patterned first metal layer of the substrate. As FIG. 2 shows, the contact pads of both arrays are in a systematic, orderly arrangement in rows and columns. The contact pads 201 of the first array have a first pitch 202 center-to-center, and each pad has a first perimeter (detail in FIGS. 4 and 6). The contact pads 210 of the second array have a second pitch 211 center-to-center, which may be different from the first pitch 202. As an example first pitch 202 may be 0.65 mm, while second pitch 211 is 0.50 mm. Further, each pad of the second array has the first perimeter.

In the example of FIG. 2, substrate 101 has a square shape with a side length 103 of about 12 mm. The substrate portion designated “B” is discussed in the magnified view of FIG. 6.

The top view of device 100 in FIG. 3 shows the second surface 101b of substrate 101 with the third array of contact pads provided by the patterned second metal layer of the substrate. The contact pads 301 of the third array have the first pitch 202 center-to-center (the same as the first array in FIG. 2), and each pad has a third perimeter (detail in FIGS. 4 and 6). The third perimeter may be the same as the first perimeter.

In the example of FIGS. 2 and 3, the contact pads of the first, the second, and the third array have circular perimeters; it is also preferred that the contact metal (preferably copper) has a solderable surface, for example a thin layer of gold or palladium.

FIG. 3 further shows in the center of substrate 101 the encapsulation 302 of a semiconductor chip. Preferred material for the encapsulation is a molding compound; alternatively, another polymer package material may be used. Inside the encapsulation, the chip may be flip-assembled or wire bonded (not shown in FIG. 3).

FIG. 4A illustrates schematically the detail of portion “A” of the sheet-like substrate 101 of FIG. 1. The core 401 of substrate 101 includes the insulating glass-epoxy material. The first surface 101a and the second surface 101b of substrate 101 alternate between an insulating “soldermask” material 402 and metallic pads exposed by windows in insulator 402. An example of a soldermask is an epoxy-based material such as a brominated novolac resin.

On the first substrate surface is a first metal layer 403, preferably copper, which is patterned to provide conductive lines and contact pads. The contact pads are exposed in the solder mask windows 405, which have a first perimeter; for many device types, the windows have a circular perimeter preferably with a diameter of about 0.3 mm. The contact pads are distributed as arrays in an orderly arrangement of rows and columns with a pitch 406 center-to-center.

As FIG. 2 shows, the contact pads of metal layer 403 are arranged in a first array with a first pitch center-to-center, and a second array with a second pitch. The first and the second pitch may be different. Pitch 406 in FIG. 4A is the first pitch; the second pitch is not shown in FIG. 4A. In addition, the contact pads of the first array have perimeter 405, and the pads of the second array may have the same perimeter.

Referring to FIG. 4A, on the second substrate surface is a second metal layer 404, preferably copper, which is patterned to provide conductive lines and contact pads. The contact pads are exposed in the solder mask windows 407; the pads have a third perimeter, which may be the same as the first perimeter, or may be different. For many device types, the windows have a circular perimeter. The contact pads are distributed as a third array in an orderly arrangement of rows and columns with a pitch 408 center-to-center, which is the same pitch as the first pitch 406.

As FIG. 4A shows, it is preferred to have the first array and the third array disposed so that the first and third perimeters of respective contact pads are concentrically aligned. In FIG. 4A, the alignment lines are designated 420 and 421, respectively. The alignment between a pad of the first array and a pad of the third array is understood as the shortest distance projection of the pads. As center lines, lines 420 and 421 determine the pitch 408 of the contact pads. When the pad alignment deviates from concentrical, for instance when window 407 is larger than window 405, then it suffices that window 405 is contained by window 407 in order to minimize area utility.

FIG. 4A illustrates conductive via connections 410 between the first patterned metal layer 403 and the second patterned metal layer 404. In the fabrication process of the vias, it is preferred to drill cylindrical holes with a fourth perimeter through the insulating core 401 (diameter for instance 75 μm), deposit a metal layer 411 around the hole perimeter, and fill the remainder of the hole with an insulator 412. In this fashion, vias 410 connect the contact pads. As indicated in FIG. 4B, small process variations may cause filling 412 to be non-level with the insulator surfaces; see below.

As FIG. 4A shows, the vias are placed in interstitial locations between adjacent contact pads (having first and third perimeters, respectively) so that the fourth perimeter does not overlap with the adjacent first and third perimeters. By adhering to this rule, only two metal layers 403 and 404 are sufficient for the substrate of FIG. 4A; any overlap of the perimeters (coupled with the risk of electrical shorts) would necessitate four metal layers for the contact pads and vias.

FIG. 4B explains a main reason for preferring an interstitial position of the vias relative to the position of the adjacent solder pads and for subsequent positioning of the solder balls on flat portions of metallizations 403 and 404. Experience has shown that the fabrication of vias 410 described above is subject to slight statistical process variations. One of these process uncertainties is the control of insulator filling 412 depicted in FIG. 4B. When the insulator filler 412 does not completely fill the via hole, the via surfaces may suffer slight dips. Consequently, metal layers 403 and 404 and solder masks 402 show dips. If solder balls 430 would be directly positioned in these non-level areas, the solder ball coplanarity would be poorly controlled. In an analogous manner, another process uncertainty may result in overfilling the vias and forming slight hillocks of the metallization, which, in turn would result in poorly controlled solder ball coplanarity, if the balls would be directly positioned on these hillocks.

For the alignment of solder balls 430 and 470 in FIG. 4B, it is emphasized that at least diameter 430a of ball 430 needs to be contained within diameter 470a of ball 470; preferably, the center lines 431 and 471 of the balls are aligned.

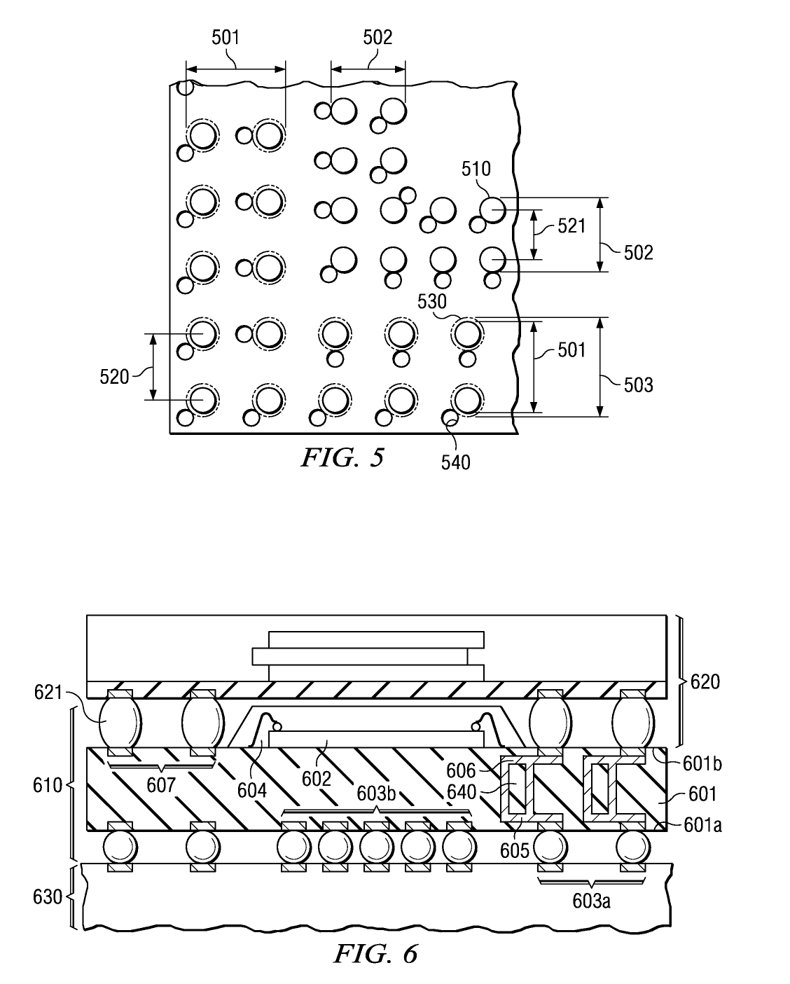

FIG. 5 is a magnified X-ray view of portion “B” of FIG. 2 to illustrate the interstitial locations of the substrate vias. The orderly rows and columns of the first array of contact pads are designated 501. The orderly rows and columns of the second array of contact pads are designated 502. The pads of both arrays are shown as having circular perimeters 510 of identical size (for instance, having 0.3 mm diameter). However, the pitch center-to-center of the arrays is different in this embodiment; pitch 520 of the first array is shown greater (for example, 0.65 mm) than the pitch 521 of the second array (for example, 0.50 mm). The orderly rows and columns of the third array, designated 503, are aligned with array 501, pad by pad. The pads of the third array are shown as having circular perimeters 530, somewhat larger than pad perimeters 510 of the first array. The first and third arrays are so disposed that the first and third perimeters of respective contact pads are concentrically aligned, or at least contained within each other.

The fourth perimeter 540 of the cylindrical vias is smaller than perimeters 510 and 530; for example, the via diameter may be 0.075 mm. As FIG. 5 shows, the vias are placed in interstitial locations so that the fourth perimeter does not overlap with the adjacent first and third perimeters. Likewise, the vias are placed in interstitial locations within the second array of contact pads so that the fourth perimeter does not overlap with the adjacent pad perimeters, which are equal to the first perimeter in this embodiment.

Since the metal of the contact pads preferably has a solderable surface, metallic reflow bodies 430 can be attached to the contact pads of the first and third array. Similarly, the contact pads of the second array have solderable surfaces. As a result, the sheet-like substrate may be applied to create a package-on-package product and assemble the product on a printed circuit board, as schematically depicted in FIG. 6. Substrate 601 is not only the substrate for chip 602 of the first device 610, but also acts as an interconnecting apparatus between the second device 620 and printed circuit board 630. As an example, second device 620 may be a memory component with one or more chips assembled inside.

FIG. 6 highlights the advantage of the second, preferably narrower pitch of the second array 603b compared to the first pitch of the contact pads on the first substrate surface 601a: If needed, the second array can accommodate a high number of input/output terminals for chip 602 (and second device 620). This advantage provides flexibility for the selection of the devices of the package-on-package assembly.

FIG. 6 further highlights the advantage of the larger solder bodies 621 on the third of contact pads on the second substrate surface 601b, compared to the smaller solder bodies on the first substrate surface 601a: Chip 602 can be wire bonded instead of flipped, and the necessary taller height of encapsulation 604 can be accommodated by solder bodies 621.

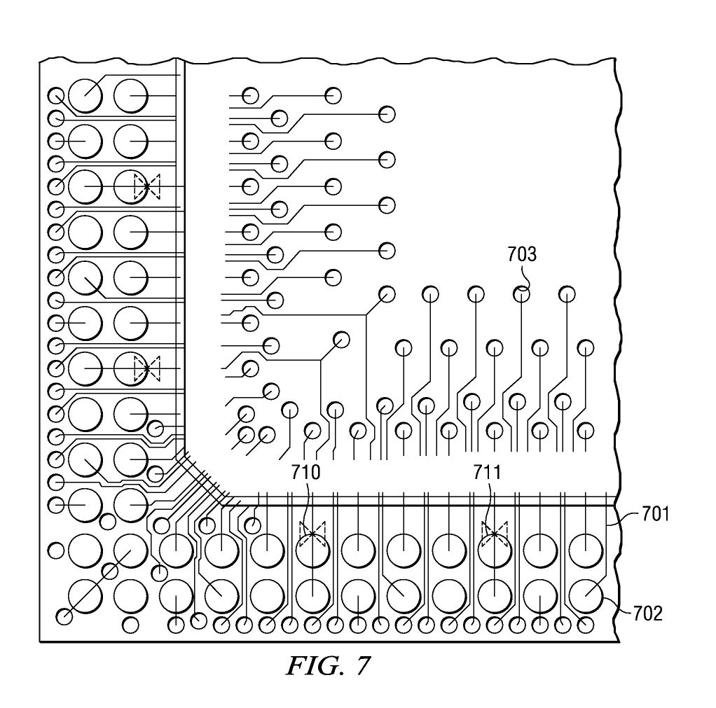

Another embodiment of the invention provides a high density of routing lines even under the constraint of only two metal layers for the substrate. The needed routing space is provided by selective depopulation of contact pads belonging to the same metal layer. FIG. 7 illustrates routing lines 701, bond pads 702, and via connections 703 of a substrate metal layer. Selectively depopulated pads 710 and 711 are highlighted; the locations of a plurality of additional sacrificed pads are also highlighted.

Opting for the smaller pitch center-to-center of the contact pads (for example, 0.5 mm) the same pitch is chosen for the pad arrays formed by the top and bottom metallizations of the substrate. As a consequence, the smaller pitch necessitates smaller solder bodies and thus requires the low-height flip-chip assembly of the semiconductor chip.

In analogy to FIGS. 1 and 4, the embodiment of FIG. 7 has an insulating sheet-like substrate with a first and a second surface. On the first surface is a first patterned metal layer with a first and a second array of contact pads. The pads of the first and the second array have the same first pitch center-to-center, and each pad has a first perimeter. The substrate has on its second surface a second patterned metal layer with a third array of contact pads, which also has the first pitch center-to-center. Furthermore, selected contact pads are depopulated from the array. Each pad of the third array has a third perimeter.

Electrically conductive vias between the first and the second metal layers connect aligned contact pads and have a fourth perimeter. The vias are placed in interstitial locations so that the fourth perimeter does not overlap with the first and third perimeters. Vias in interstitial locations can be provided by disposing the first array and the third array so that the first and third perimeters of respective contact pads are concentrically aligned, or at least contained within each other (so that the perimeters do not intersect).

Routing lines to the contact pads of the third array are distributed in the second metal layer so that required space is provided by the selectively depopulated contact pads. This sacrifice enables a high density of routing line even under the constraint of only two metal layers.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies to products using any type of semiconductor chip (such as memory, ASIC, microprocessor, etc.), discrete or integrated circuit, and the material of the semiconductor chip may comprise silicon, silicon germanium, gallium arsenide, or any other semiconductor or compound material used in integrated circuit manufacturing.

As another example, the need for encapsulating the chip on the substrate of the first device can be omitted when the chip is not assembled by wire bonding but by flip-chip technology.

It is therefore intended that the appended claims encompass any such modifications or embodiment.

We claim:

1. An apparatus comprising:
an insulating sheet-like substrate having a first and a second surface;
a first patterned metal layer on the first surface including a first and a second array of contact pads;
the contact pads of the first array having a first pitch center-to-center, and each pad having a first perimeter;
the contact pads of the second array having a second pitch center-to-center, and each pad having the first perimeter;
a second patterned metal layer on the second surface including a third array of contact pads having the first pitch center-to-center, and each pad having a third perimeter;
vias between the first and the second metal layers connecting contact pads, each via having a fourth perimeter; and
the vias placed in interstitial locations so that the fourth perimeter does not intersect with the adjacent first and third perimeters.

2. The apparatus according to claim 1 further having the first array and the third array so disposed that the first and third perimeters of respective contact pads are concentrically aligned.

3. The apparatus according to claim 1 wherein the contact pads of the first array, the second array, and the third array have a solderable surface.

4. The apparatus according to claim 4 wherein solder balls are attached to the contact pads of the first and the second array, which have an approximately hemispherical shape with a diameter between about 0.25 and 0.35 mm and a height between about 0.18 and 0.28 mm.

5. The apparatus according to claim 4 wherein the solder balls on the contact pads of the first and the second array are reflowed to connect to a printed circuit board.

6. The apparatus according to claim 4 wherein solder balls on the contact pads of the third array are connected to a second device.

7. The apparatus according to claim 1 further including a semiconductor chip connected by wire bonds or by flip-chip to the second surface of the substrate.

8. The apparatus according to claim 1 wherein the insulating sheet-like substrate is square-shaped with a side length of about 12 mm and a thickness between about 0.26 and 0.34 mm.

9. The apparatus according to claim 1 wherein the first pitch center-to-center is 0.65 mm.

10. The apparatus according to claim 1 wherein the second pitch center-to-center is 0.15 mm smaller than the first pitch.

11. The apparatus according to claim 1 wherein the contact pads of the first array have a circular first perimeter with a diameter of about 0.3 mm.

12. The apparatus according to claim 1 wherein the contact pads of the third array have a circular third perimeter with a diameter about equal to the first diameter.

13. The apparatus according to claim 1 wherein the vias have about cylindrical shape with a diameter of about 75 μm.

14. An apparatus comprising:
an insulating sheet-like substrate having a first and a second surface;
a first patterned metal layer on the first surface including a first and a second array of contact pads;
the contact pads of the first and the second array having a first pitch center-to-center and each pad having a first perimeter;
a second patterned metal layer on the second surface including a third array of contact pads having the first pitch center-to-center and selected contact pads depopulated from the array, and each pad having a third perimeter;
vias between the first and the second metal layers connecting contact pads, each via having a fourth perimeter;
the vias placed in interstitial locations so that the fourth perimeter does not intersect with the adjacent first and third perimeters; and
routing lines to the contact pads of the third array distributed in the second metal layer so that required space is provided by selectively depopulated contact pads.

15. The apparatus according to claim 14 further having the first array and the third array so disposed that the first and third perimeters of respective contact pads are concentrically aligned.
